(19) United States
(12) Patent Application Publication
(10) Pub. No.: US 2012/0044634 A1
(43) Pub. Date: Feb. 23, 2012

(54) HEAT DISSIPATION APPARATUS

(75) Inventors: GUO-HE HUANG, Shenzhen City (CN); YANG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/956,692

(22) Filed: Nov. 30, 2010

(30) Foreign Application Priority Data
Aug. 17, 2010 (CN) 201010255452.6

(51) Int. Cl. H05K 7/20

(52) U.S. Cl. 361/679.49; 361/679.54

(57) ABSTRACT

A heat dissipation apparatus includes a computer case having a base plate, a motherboard positioned on the base plate, and a heat sink. The motherboard includes a first heat source positioned thereon. The heat sink is positioned on the first heat source and thermally contacts with the first heat source. The motherboard includes a second heat source located on a first side of the heat sink. An angle between the second heat source and a motherboard plane is greater than 0 degrees and less than 90 degrees. Airflow from outside of the computer case is able to flow through a top surface and a bottom surface of the second heat source to dissipate heat for the first and second heat sources.

### BACKGROUND

1. Technical Field

The disclosure generally relates to a heat dissipation apparatus, especially to a heat dissipation apparatus used to dissipate heat from memory chips in a computer.

2. Description of Related Art

All-in-One computers are desktop computers that combine the monitor into the same case as the CPU. A typical all-in-one computer includes a motherboard, a heat sink and a cooling fan. A plurality of heat sources (e.g., CPU, north bridge chip, south bridge chip, hard disc, memory chip) are attached on the motherboard. In order to save space in the All-in-One computers, the memory chips are positioned parallel on the motherboard. Cold airflow enters the computer, passes through an air channel between the hard disc and the motherboard, and dissipates heat from the hard disc, the CUP and other heat sources. In addition, the heated airflow is then sucked out from the computer by a plurality of fans. The cold airflow only flows through a top of the memory chips. A special fan for the memory chips is needed and the typical heat dissipation apparatus has low heat dissipation efficiency.

Therefore there is a need for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a heat dissipation apparatus.

FIG. 2 is an assembled view of an embodiment of the heat dissipation apparatus of FIG. 1.

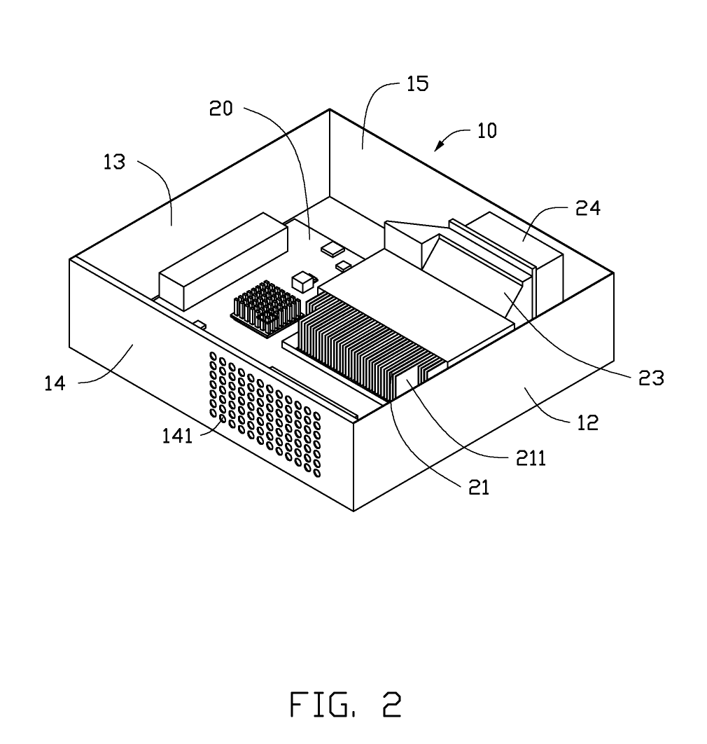

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

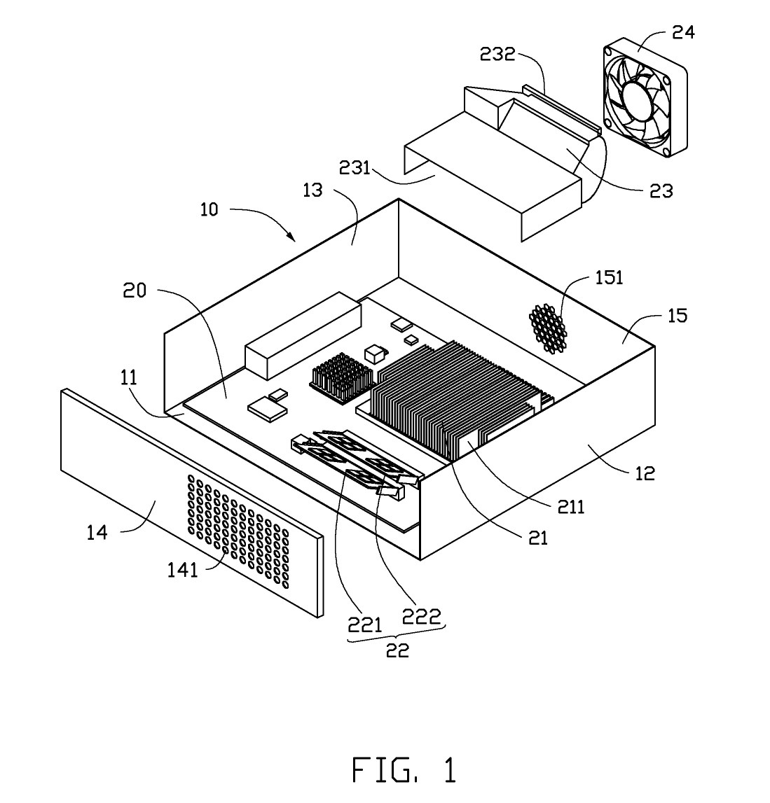

Referring to FIG. 1, an embodiment of a heat dissipation apparatus includes a computer case 10. The computer case 10 includes a base plate 11, a first side plates 12 and a second side plate 13, a front plate 14 and a back plate 15. The first and second side plates 12, 13, the front plate 14 and the back plate 15 are perpendicular to the base plate 11.

The base plate 11 includes a motherboard 20 positioned thereon. The motherboard 20 includes a first heat source (not shown) thereon. A heat sink 21 is positioned on the first heat source and is in thermal contact with the first heat source. The heat sink 21 includes a plurality of fins 211. A width of the fins 211 at two sides of the heat sink 21 is less than that of the fins 211 in the middle. The motherboard 20 includes a second heat source 22 positioned thereon at a first side of the heat sink 21. The motherboard 20 includes an air duct 23 and a fan 24 positioned thereon at a second side of the heat sink 21. An angle between the second heat source 22 and the base plate 11 is greater than 0 degrees and less than 90 degrees. The airflow from outside is sucked into the computer case 10, and the airflow diagonally passes through the surface of the second heat source 22 to dissipate heat for the first heat source and the second heat source 22. The front plate 14 defines a plurality of air inlet holes 141 that open towards the second heat source 22. In one embodiment, the angle is 30 degrees; the second heat source 22 includes a first memory chip 221 and a second memory chip 222; and the first heat source is a CPU.

The air duct 23 includes an air inlet opening 231 and an air outlet opening 232. The air inlet opening 231 opens towards the second side of the heat sink 21. The air outlet opening 232 opens towards the fan 24. The back plate 15 defines a plurality of air outlet holes 151 thereon. The plurality of air outlet holes 151 open towards the fan 24. The airflow passing through the second heat source 22 and the heat sink 21 is blown out of the computer case 10 by the plurality of air outlet holes 151.

When the computer is powered up, the fan 24 can rotate. The cool air from outside the computer case 10 is sucked into the computer case 10 by the fan 24 through the air inlet holes 141. A speed of the cool airflow is accelerated when passing through the first and second memory chips 221, 222, and the heat sink 21. Some of the cool airflow diagonally passes through a bottom surface of the first memory chip 221 and a top surface of the second memory chip 222. And some of the cool airflow passes through a top surface of the first memory chip 221 and a bottom surface of the second memory chip 222 through a gap between the first and second memory chips 221 and 222. The cool air displaces the warm air heated by the first and second memory chips 221, 222 and the heat sink 21. The warm air is blown out of the computer case 10 by the fan 24 through the air duct 23 and the air outlet holes 151.

Using a software application called Icepak to simulate the efficiency of the heat dissipation system, the following results of one embodiment shown below were obtained. The simulated conditions are set to: initial ambient temperature 35 degrees Celsius. A power dissipation of the first heat source is 95 W. A power dissipation of the second heat source 22 is 20 W. The heat sink 21 has a dimension of 85.3 millimeter (mm)×81 mm×87.7 mm (length×width×height). The fan 24 has a dimension of 92 mm×92 mm×25 mm (length×width×height). A maximum air flow rate of the fan 24 is 35.32 cubic feet per minute (cfm). A rated speed of the fan 24 is 2000 revolutions per minute (rpm). A maximum static pressure of the fan 24 is 0.084 inch-H₂O. The simulation according to the set conditions shows that the maximum temperature on the surfaces of the first and second memory chips 221, 222 is 71.9354 degrees Celsius when the heat dissipation apparatus of the disclosure. A threshold value of the temperature on the surfaces of the first and second memory chips 221, 222 is 85 degrees Celsius. The maximum temperature on the surfaces of the first and second memory chips 221, 222 is less than the threshold value. The fan for the first and second memory chips 221, 222 in the typical heat dissipation apparatus is not needed and heat dissipation efficiency is improved.

It is to be understood, however, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A heat dissipation apparatus, comprising:
a computer case comprising a base plate;
a motherboard positioned on the base plate; wherein the motherboard comprises a first heat source positioned thereon; and
a heat sink positioned on the first heat source and configured to thermally contact with the first heat source; wherein the motherboard comprises a second heat source located on a first side of the heat sink; an angle between the second heat source and a motherboard plane is greater than 0 degrees and less than 90 degrees; and airflow from outside of the computer case is able to diagonally flow through a top surface and a bottom surface of the second heat source to dissipate heat for the first and second heat sources.

2. The heat dissipation apparatus of claim 1, wherein the angle between the second heat source and the motherboard plane is about 30 degrees.

3. The heat dissipation apparatus of claim 1, wherein the motherboard further comprises an air duct and a fan positioned on a second side of the heat sink; airflow from outside of the computer case is able to be sucked into the computer case by the fan.

4. The heat dissipation apparatus of claim 3, wherein the air duct comprises an air inlet opening and an air outlet opening; the air inlet opening opens towards the second side of the heat sink; and the air outlet opening opens towards the fan.

5. The heat dissipation apparatus of claim 3, wherein the computer case further comprises a back plate that is perpendicular to the base plate; the back plate defines a plurality of air outlet holes; the plurality of air outlet holes open towards the fan; and airflow passing through the second heat source and the heat sink is able to be blown out of the computer case by the plurality of air outlet holes.

6. The heat dissipation apparatus of claim 1, wherein the heat sink comprises a plurality of fins; and a width of the plurality of fins located on the sides of the heat sink is less than that of the plurality of fins located in the middle of the heat sink.

7. The heat dissipation apparatus of claim 1, wherein the first heat source is a CPU; and the second heat source comprises a plurality of memory chips.

8. A heat dissipation apparatus, comprising:
a base plate;
a motherboard positioned on the base plate; wherein the motherboard comprises a first heat source positioned thereon; and
a heat sink positioned on the first heat source and configured to thermally contact with the first heat source; wherein the motherboard comprises a second heat source located on a first side of the heat sink; an angle between the second heat source and a motherboard plane is greater than 0 degrees and less than 90 degrees; and airflow from outside is able to flow through a top surface and a bottom surface of the second heat source to dissipate heat for the first and second heat sources.
